(19) United States
(12) Patent Application Publication
(10) Pub. No.: US 2018/0138113 A1
(43) Pub. Date: May 17, 2018

(54) SEMICONDUCTOR SYSTEM AND DEVICE PACKAGE INCLUDING INTERCONNECT STRUCTURE

(71) Applicant: Advanced Semiconductor Engineering, Inc., Kaohsiung (TW)

(72) Inventors: Chien-Hua CHEN, Kaohsiung (TW); Teck-Chong LEE, Kaohsiung (TW); Yung-Shun CHANG, Kaohsiung (TW)

(73) Assignee: Advanced Semiconductor Engineering, Inc.

(21) Appl. No.: 15/352,529

(22) Filed: Nov. 15, 2016

(51) Int. Cl. H01L 23/498; H01L 21/48; H01L 21/56; H01L 23/00; H05K 3/40; H01L 21/683

(52) U.S. Cl. CPC H01L 23/49827; H01L 2221/68359; H01L 23/49894; H01L 23/49816; H01L 23/49866; H01L 21/486; H01L 21/565; H01L 21/4853; H01L 21/4857; H01L 23/49822; H01L 24/49; H01L 24/32; H01L 24/73; H05K 3/4061; H01L 21/6835; H01L 2224/32225; H01L 2224/48091; H01L 2224/48106; H01L 2224/48228; H01L 2224/49175; H01L 2224/73265; H01L 2924/15738; H01L 2924/15701; H01L 2924/01047; H01L 2924/0105; H05K 2203/085; H05K 2203/086; H01L 2221/68327; H01L 23/49838

(57) ABSTRACT

A semiconductor device package includes a semiconductor chip, a glass substrate having a first surface facing the semiconductor chip and a second surface opposite to the first surface, the glass substrate defining a hole that traverses the glass substrate from the first surface to the second surface, an interconnect structure disposed in the hole, and a conductive bump disposed adjacent to the interconnect structure and protruded from the second surface, wherein the conductive bump and the interconnect structure include a same material.

### BACKGROUND

Interposers have been used in packaged integrated circuits (ICs), functioning as a miniaturized printed circuit board (PCB) that can be used to implement three dimensional (3D) or two-point-five dimensional (2.5D) integrated circuits or system on package (SoP) platforms. Through-silicon vias (TSVs) can provide routing paths through the interposer between dies mounted on opposite sides of the interposer. An interposer may be made of glass. A through glass via (TGV) can be formed in a glass interposer to electrically connect a solder bump to a semiconductor chip when the solder bump and the semiconductor chip are mounted on opposite sides of the interposer. The TGV can be formed by electroplating copper into a hole of the glass substrate. However, this electroplating process can be inefficient. Moreover, voids (e.g., gaps in a material that fills the hole) can form during the electroplating process, especially when an aspect ratio (i.e. a ratio of depth to width) of the hole is large. Accordingly, there is a need to provide a solution to the above problem.

### SUMMARY

In some embodiments, according to one aspect, a semiconductor device package includes a semiconductor chip, a glass substrate having a first surface facing the semiconductor chip and a second surface opposite to the first surface, the glass substrate defining a hole that traverses the glass substrate from the first surface to the second surface, an interconnect structure disposed in the hole, and a conductive bump disposed adjacent to the interconnect structure and protruded from the second surface, wherein the conductive bump and the interconnect structure include a same material.

In some embodiments, according to another aspect, a semiconductor device package includes a glass substrate having a first surface and a second surface opposite to the first surface, the glass substrate defining a hole that traverses the glass substrate and comprising a first opening with a first diameter on the first surface and a second opening with a second diameter on the second surface, and an interconnect structure disposed in the hole, wherein the second diameter is greater than the first diameter.

In some embodiments, according to another aspect, a system for forming an interconnect structure includes a substrate defining a plurality of holes formed in a surface of the substrate, and an injecting device, disposed above the substrate, the injection device including: a slot, configured to be loaded with a conductive material, a pumping head disposed adjacent to a top of the slot, and a filling head, disposed adjacent to a bottom of the slot and configured to fill a selected hole of the plurality of holes to form an interconnect structure, wherein the pumping head is configured to pump gas into the slot and to thereby push the conductive material into the selected hole.

### BRIEF DESCRIPTION OF THE DRAWINGS

Aspects of some embodiments of the present disclosure are best understood from the following detailed description when read with the accompanying figures. It is noted that various features of the objects and components depicted in the figures may not necessarily be drawn to scale. Some dimensions of the various objects and components depicted in the figures may be arbitrarily increased or reduced for purposes of providing a useful example for discussion.

FIG. 1 is a cross-sectional diagram illustrating a semiconductor device package in accordance with some embodiments.

FIG. 2 is a diagram illustrating an interconnect structure and a conductive bump in accordance with some embodiments.

FIG. 3 is a diagram illustrating an interconnect structure and a conductive bump in accordance with some embodiments.

FIG. 4 is a diagram illustrating an interconnect structure and a conductive bump in accordance with some embodiments.

FIG. 5 is a flowchart illustrating a method of forming a semiconductor device package in accordance with some embodiments.

FIG. 6 is a diagram illustrating a glass substrate having a plurality of holes in accordance with some embodiments.

FIG. 7 is a diagram illustrating a photoresist layer patterned on a glass substrate in accordance with some embodiments.

FIG. 8 is a diagram illustrating an adhesive layer and a carrier adhered to the adhesive layer of a glass substrate in accordance with some embodiments.

FIG. 9 is a diagram illustrating a thinned down glass substrate in accordance with some embodiments.

FIG. 10 is a diagram illustrating a plurality of passive devices formed on a glass substrate in accordance with some embodiments.

FIG. 11 is a diagram illustrating an integrated passive device structure formed on a glass substrate in accordance with some embodiments.

FIG. 12 is a diagram illustrating a semiconductor chip attached on an integrated passive device structure in accordance with some embodiments.

FIG. 13 is a diagram illustrating an insulating molding compound disposed on a semiconductor chip in accordance with some embodiments.

FIG. 14 is a diagram illustrating an injecting device in accordance with some embodiments.

FIG. 15 is a diagram illustrating an injecting device in accordance with some embodiments.

### DETAILED DESCRIPTION

The following disclosure provides many different embodiments, or examples, for implementing different features of the subject matter described herein. Specific examples of components and arrangements of the components are described below for explanatory purposes. The described components and arrangements of components are examples and are not intended to be limiting. For example, a description of the formation of a first feature over or on a second feature in the description that follows may refer to embodiments in which the first and second features are formed in direct contact, and may also refer to embodiments in which additional features may be formed or disposed between the first and second features, such that the first and second features may not be in direct contact. In addition, reference numerals and/or letters may be repeated in the various examples provided below. This repetition is for purposes of discussion and is meant to promote simplicity and clarity, and does not in itself dictate a relationship between the various embodiments and/or configurations discussed.

Embodiments of the present disclosure are discussed in detail below. It should be appreciated, however, that the subject matter of the present disclosure can be embodied in a wide variety of contexts. The specific embodiments discussed are merely illustrative and do not limit the scope of the disclosure.

Further, spatially relative terms, such as “beneath,” “below,” “lower,” “above,” “upper”, “higher,” “left,” “right” and the like, may be used herein for ease of description to describe one element or feature's relationship to another element(s) or feature(s) illustrated in the figures. The spatially relative terms are intended to encompass different orientations of the device in use or operation in addition to the orientation depicted in the figures. The apparatus may be otherwise oriented (e.g., rotated 90 degrees or at other orientations) and the spatially relative descriptors used herein may likewise be interpreted accordingly. It will be understood that when an element is referred to as being “connected to” or “coupled to” another element, it may be directly connected to or coupled to the other element, or intervening elements may lie between the connected or coupled elements.

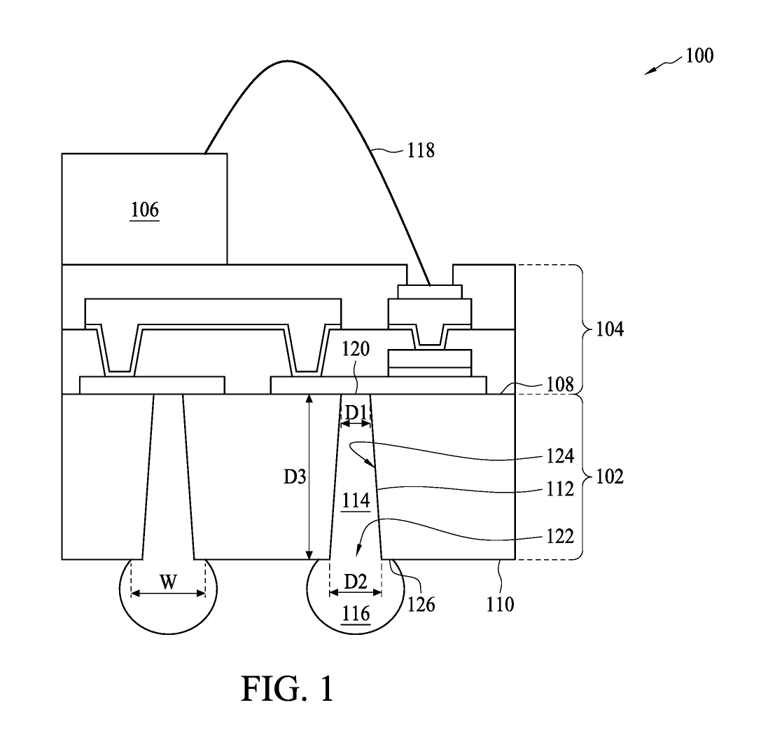

FIG. 1 is a cross-sectional diagram illustrating a portion of a semiconductor device package 100 in accordance with some embodiments. The device package 100 is a 3D or 2.5D system on package (SoP) assembly. The semiconductor device package 100 includes a glass substrate 102, an integrated passive device (IPD) structure 104, and a semiconductor chip 106. The glass substrate 102 has a first surface 108 facing the semiconductor chip 106 and a second surface 110 opposite to the first surface 108. The IPD structure 104 is disposed between the glass substrate 102 and the semiconductor chip 106. At least one hole 112 is defined by the glass substrate 102. Specifically, the hole 112 traverses the glass substrate 102 from the first surface 108 to the second surface 110. An interconnect structure 114 is disposed in the hole 112. A conductive bump 116, which can be contiguous with the interconnect structure 114, protrudes from the glass substrate 102 (e.g., the conductive bump 116 is disposed adjacent to the interconnect structure 114 and protrudes from the second surface 110 the glass substrate 102). According to some embodiments, the conductive bump 116 is contiguously connected to the interconnect structure 114. For example, the conductive bump 116 and the interconnect structure 114 can be integrally formed with one another as a monolithic structure. The conductive bump 116 and the interconnect structure 114 can be composed of the same material, or of a similar material. For example, the material of the conductive bump 116 and the interconnect structure 114 can include tin (Sn) or alloy of tin (Sn) and silver (Ag). The material of the conductive bump 116 and the interconnect structure 114 can include a magnetic material. In some embodiments, the glass substrate 102 may be replaced with silicon, SiO₂, and/or other silicon-based substrate.

The IPD structure 104 is disposed on the first surface 108 of the glass substrate 102. The semiconductor chip 106 is disposed on the IPD structure 104. According to some embodiments, at least one bonding wire 118 is arranged to electrically connect the semiconductor chip 106 and the IPD structure 104. Some embodiments do not include the bonding wire 118, and the electrical connection can instead be made via a flip chip implementation. The IPD structure 104 may comprise, for example, high-density trench capacitors, metal-insulator-metal (MIM) capacitors, resistors, high-Q inductors, PIN diodes or Zener diodes. These devices and components and the semiconductor chip 106 can be integrated into one package, which can help increase functional reliability of the system.

According to some embodiments, the hole 112 has a first opening 120 with a first diameter D1 defined by the first surface 108 and a second opening 122 with a second diameter D2 defined by the second surface 110, and the second diameter D2 is greater than the first diameter D1. For example, D2 can be greater than about 1.1 times D1 or greater than about 1.2 times D1. Moreover, the diameter of the hole 112 gradually decreases or monotonically decreases along a direction from the second opening 122 to the first opening 120. However, not all embodiments exhibit this feature. According to some embodiments, the second diameter D2 may be substantially equal to the first diameter D1. Although the hole depicted in FIG. 1 and described herein is approximately circular in cross-sectional shape, in other embodiments, the hole need not be circular and can be, for example, any elliptical or polygonal shape. Furthermore, although the term “diameter” is used here, for embodiments in which the hole is not circular, the term “width” or “maximum width” can be substituted for “diameter,” as appropriate.

According to some embodiments, the hole 112 has a depth D3 measured from the first opening 120 to the second opening 122, and a ratio of the depth D3 to the second diameter D2 is in a range from about 5 to about 50. This aspect ratio of hole 112 is relatively large in comparison to other TGVs.

In addition, according to some embodiments, the maximum width of the conductive bump 116 is greater than the second diameter D2. Specifically, when the conductive bump 116 is protruded from the second surface 110 of the glass substrate 102, the conductive bump 116 has a flat surface 126 directly contacted and adhered with the second surface 110, and the flat surface 126 has a width W greater than the second diameter D2. Depending on the practical implementation, the width W may be the maximum width of the conductive bump 116.

The hole 112 can be filled to form the interconnect structure 114. According to some embodiments, the interconnect structure 114 is directly contacted and adhered with an inner surface 124 of the hole 112. By using below-described TGV forming methods to fill the hole 112 to form the interconnect structure 114, the hole 112 can be filled with a reduced chance of voids formed in the interconnect structure 114. Therefore, the reliability of the TGV and of the TGV forming processes described herein is improved compared to that of other TGVs formed by an electroplating process.

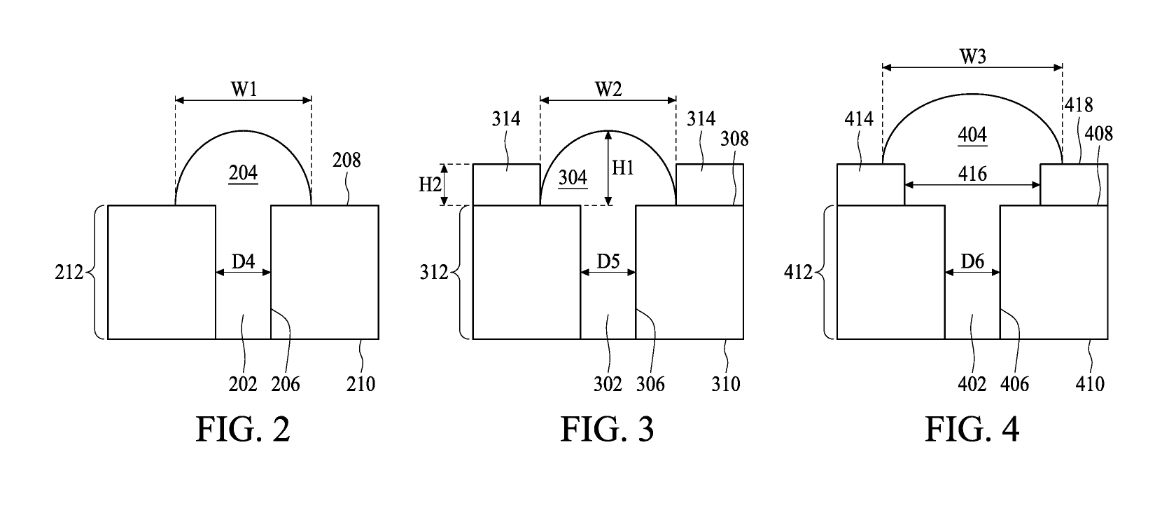

FIG. 2 is a diagram illustrating an interconnect structure 202 and a conductive bump 204 in accordance with some embodiments. In the depicted embodiments, a hole 206 defined by a glass substrate 212 traverses the glass substrate 212 from a first surface 208 of the glass substrate 212 to a second surface 210 of the glass substrate 212. The hole 206 has a substantially constant diameter D4. The interconnect structure 202 is contiguously connected to the conductive bump 204. The conductive bump 204 protrudes from the first surface 208 of the glass substrate 212. The conductive bump 204 can have an approximately hemispheric shape. A portion of the conductive bump 204 has a width W1, at least a part of which directly contacts and is adhered to the first surface 208 of the glass substrate 212. In the depicted embodiments, the first surface 208 of the glass substrate 212 is exposed except for a portion in contact with the conductive bump 204. However, in other embodiments other portions or an entirety of the first surface 208 may not be exposed.

FIG. 3 is a diagram illustrating an interconnect structure 302 and a conductive bump 304 in accordance with some embodiments. In the depicted embodiments, a hole 306 defined by a glass substrate 312 traverses the glass substrate 312 from a first surface 308 of the glass substrate 312 to a second surface 310 of the glass substrate 312. The hole 306 has a substantially constant diameter D5. The interconnect structure 302 is contiguously connected to the conductive bump 304. The conductive bump 304 protrudes from the first surface 308 of the glass substrate 312, and the conductive bump 304 can have an approximately hemispheric shape. A portion of the conductive bump 304 has a width W2, at least a part of which directly contacts and is adhered to the first surface 308 of the glass substrate 312. In the depicted embodiments, a passivation layer 314 is disposed over or in contact with a portion of the first surface 312 not covered by the conductive bump 304. The passivation layer 314 is an insulating layer. The conductive bump 304 has a first height H1 (e.g., a maximum height measured from the flat surface of the hemispheric conductive bump 304 to an opposite curved surface) and the passivation layer 314 has a second height H2 measured from a first surface of the passivation layer 314 in contact with the first surface 308 to a second surface of the passivation layer 314 opposite to the first surface of the passivation layer 314. In the depicted embodiments, the first height H1 is greater than the second height H2. However, in other embodiments, the second height H2 may the same as or greater than the first height H1.

FIG. 4 is a diagram illustrating an interconnect structure 402 and a conductive bump 404 in accordance with some embodiments. A hole 406 defined by the a glass substrate 412 traverses the glass substrate 412 from a first surface 408 of the glass substrate 412 to a second surface 410 of the glass substrate 412. The hole 406 has a substantially constant diameter D6. The interconnect structure 402 is contiguously connected to the conductive bump 404. A passivation layer 414 is disposed on the first surface 408 of the glass substrate 412. The passivation layer 414 defines an opening having a width 416 such that the passivation layer 414 is not disposed above the hole 402. The width 416 is greater than the diameter D6 of the hole 406. The passivation layer 414 has a first surface in contact with the first surface 408 of the glass substrate 412, and a second surface 418 opposite the first surface of the passivation layer 414. The conductive bump 404 is arranged to protrude from the first surface 408 of the glass substrate 412 and to further protrude from the second surface 418 of the passivation layer 414. A first portion of the conductive bump 404 has a width W3, at least a part of which directly contacts and is adhered to the second surface 418 of the passivation layer 414. A second portion of the conductive bump 404 has a width equal to the width 416, at least a part of which directly contacts and is adhered to the first surface 408 of the glass substrate 412.

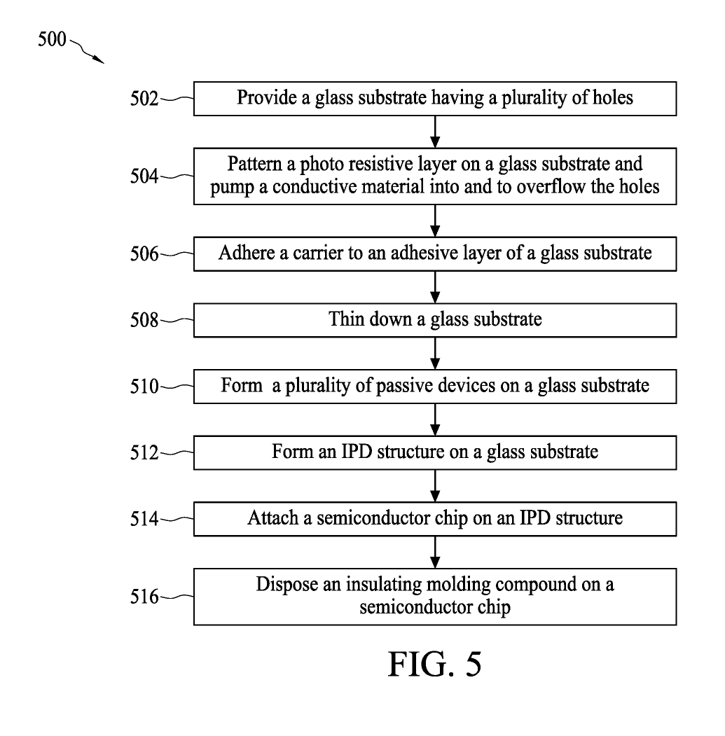

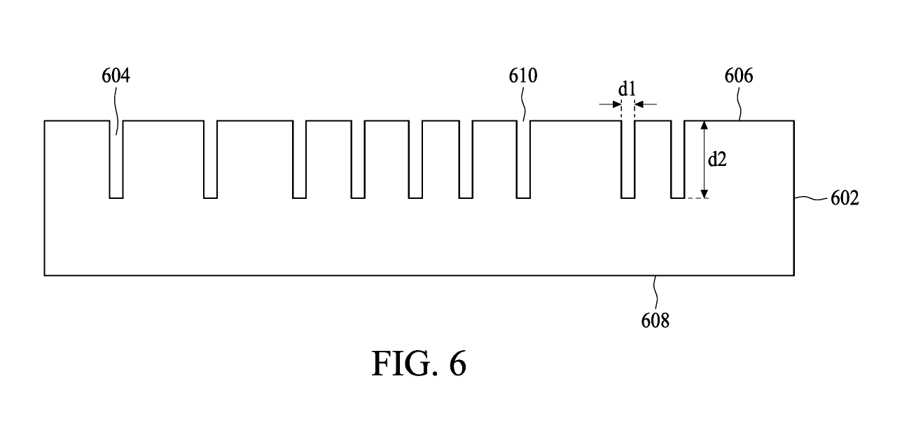

FIG. 5 is a flowchart showing operations of a method 500 of forming a semiconductor device package in accordance with some embodiments. In operation 502, a glass substrate 602 defining a plurality of holes 604 is provided, as depicted in FIG. 6. The glass substrate 602 has a first surface 606 and a second surface 608 opposite to the first surface 606, and each of the holes 604 has a first opening 610 with a first diameter d1 at the first surface 606. According to some embodiments, each of the holes 604 has a tapered shape. The first diameter d1 at the first opening 610 of each hole 604 is the largest diameter of each hole 604. In other words, each hole 604 is widest at the first surface 606. The depth of the hole 604 is d2, measured from the first surface 606 in a direction towards the second surface 608. The hole 604 does not traverse the entirety of the glass substrate 602 (e.g., does not reach the second surface 608). According to some embodiments, a ratio of the depth d2 to the first diameter d1 is in a range from about 5 to about 50.

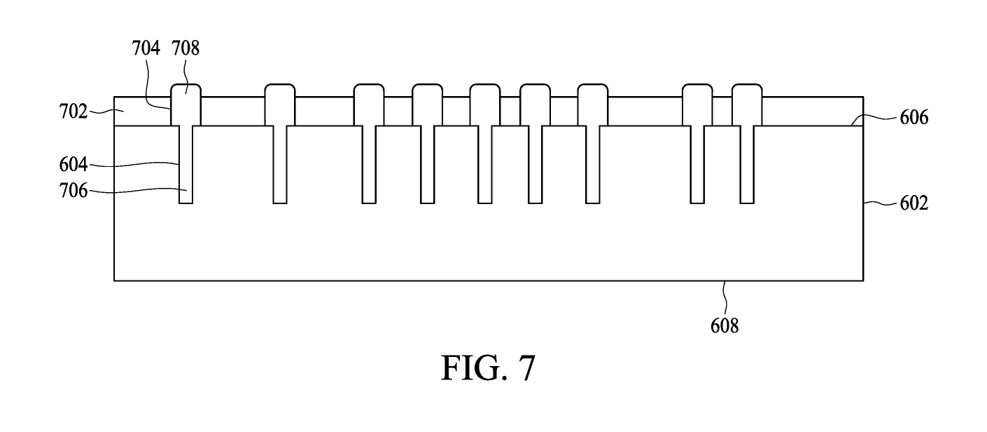

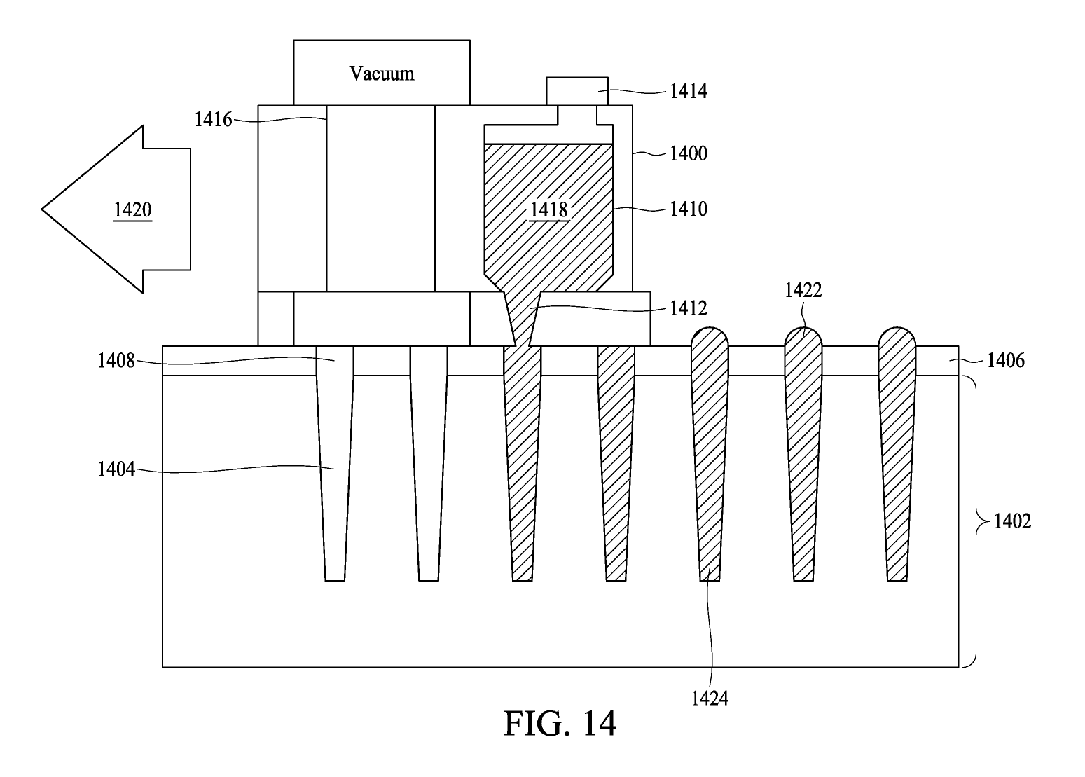

In operation 504, a photoresist layer 702 is patterned on the first surface 606 of the glass substrate 602, as depicted in FIG. 7. According to some embodiments, a plurality of openings 704 defined by the photoresist layer 702 corresponding to the holes 604 are formed in the photoresist layer 702, and can respectively expose the holes 604. A diameter of each opening 704 of the photoresist layer 702 may greater than the corresponding first diameter d1 of the corresponding hole 604. Then, a conductive material is pumped into the holes 604 through the openings 704 of the photoresist layer 702 to form a plurality of interconnect structures 706 in a near-vacuum environment (e.g., an environment in which a pressure is low, such as about 10⁻¹ Pascal or below, about 10⁻³ Pascal or below, about 10⁻⁵ Pascal or below, or about 10⁻⁷ Pascal or below, or in which a particle count is low). The conductive material is pumped and overflows the holes 604 and the openings 704 of the photoresist layer 702, forming a plurality of conductive bumps 708. As the interconnect structures 706 are formed by pumping the conductive material into the holes 604 in a near-vacuum environment, the conductive material can more completely fill the holes 604. The vacuum filing helps to prevent voids from forming in the interconnect structure 706 during the formation process, as described in more detail below in reference to FIG. 14.

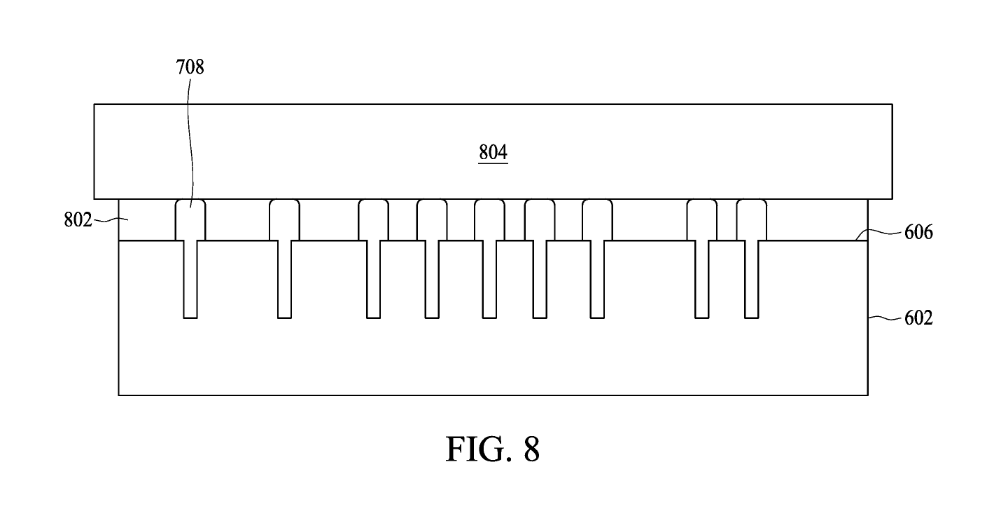

In operation 506, the photoresist layer 702 is removed to expose the first surface 606 of the glass substrate 602 and the conductive bumps 708 as depicted in FIG. 8. Then, an adhesive layer 802 is disposed over the first surface 606 of the glass substrate 602 and the conductive bumps 708. According to some embodiments, the adhesive layer 802 is arranged to cover the conductive bumps 708; in other embodiments, at least one of the conductive bumps 708 is left exposed. Then, a carrier 804 is adhered to the adhesive layer 802 in order to carry and overturn the glass substrate 602.

According to some embodiments, the interconnect structures 706 and the conductive bumps 708 are formed by a single pumping process. This helps make the present method 500 a relatively streamlined method of forming a semiconductor device package.

In addition, because the diameter of a conductive bump 708 is greater than the diameter of the corresponding interconnect structure 706, the corresponding conductive bump 708 has a greater contacting area to connect to an external pad. According to some embodiments, the diameter of the conductive bump 708 can be adaptively adjusted by selecting the diameter of the corresponding opening 704 of the photoresist layer 702.

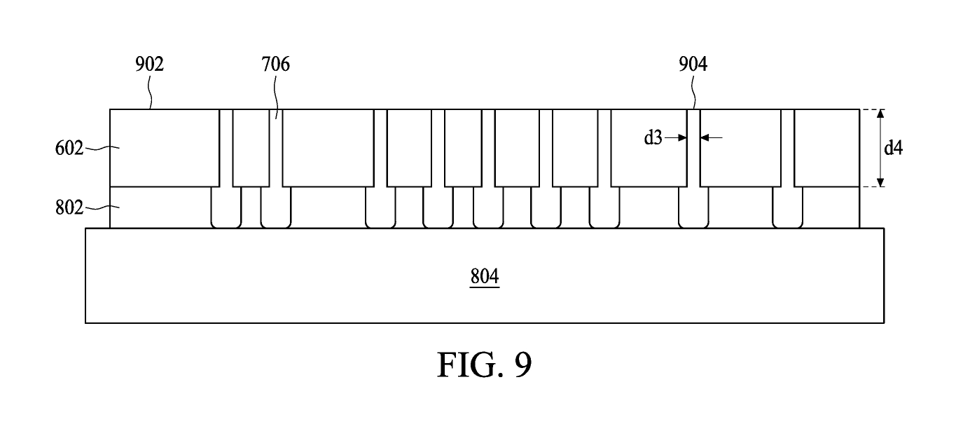

In operation 508, the glass substrate 602 is flipped by the carrier 804, and the glass substrate 602 is thinned down (material is removed) at the second surface 608 to form a third surface 902, as depicted in FIG. 9. A plurality of second openings 904 on the third surface 902 expose bottom parts of the interconnect structures 706, respectively. Each of the second openings 904 may have a second diameter d3. As the hole 604 is tapered, the second diameter d3 of the second opening 904 is smaller than the first diameter d1 of the first opening 610. The thinned down glass substrate 602 now has a thickness d4. The thickness d4 is smaller than the depth d2. However, the ratio of the thickness d4 to the first diameter d1 may still be within a range from about 5 to about 50.

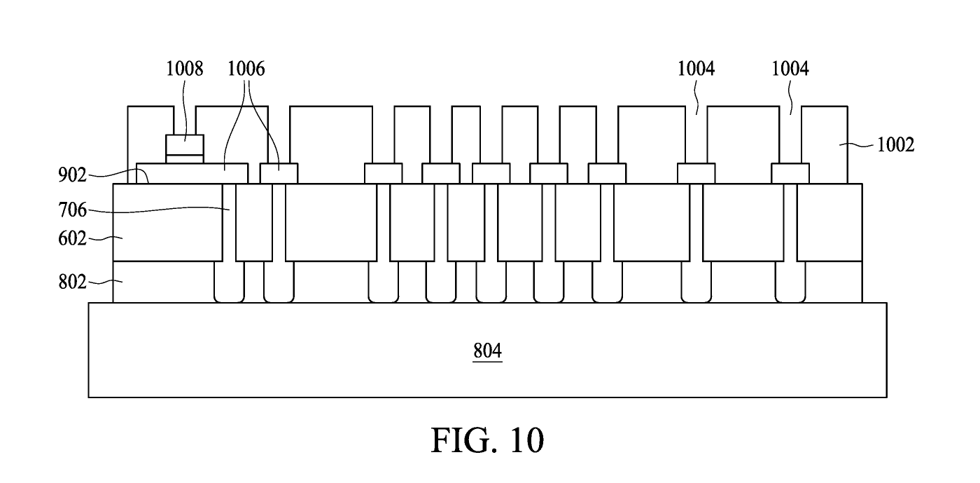

In operation 510, a plurality of passive devices 1008 and conductive structures 1006 are formed on the third surface 902 of the glass substrate 602, as depicted in FIG. 10. The conductive structures 1006 are respectively are disposed such that they cover respective openings 904 of the glass substrate 602. The passive devices 1008 are disposed such that each passive device 1008 is in electrical contact with at least one conductive structure 1006. The passive devices 1008 are separated by a first passivation layer 1002. The passivation layer 1002 is disposed on at least a portion of the third surface 902, and may cover at least a portion of at least one conductive structure 1006 and may cover at least a portion of at least one passive device 1008. A plurality of holes 1004 are formed in the first passivation layer 1002. The holes 1004 are disposed such that at least a portion of at least one conductive structure 1006 or one passive device 1008 lies exposed at a bottom of each hole 1004. The passive devices 1008 may be, for example, one or more high-density trench capacitors, MIM capacitors, resistors, high-Q inductors, PIN diodes or Zener diodes. In the depicted embodiment, an MIM capacitor 1008 is formed above the glass substrate 602, and the MIM capacitor 1008 is electrically connected to an interconnect structure 706 through a corresponding conductive structure 1006.

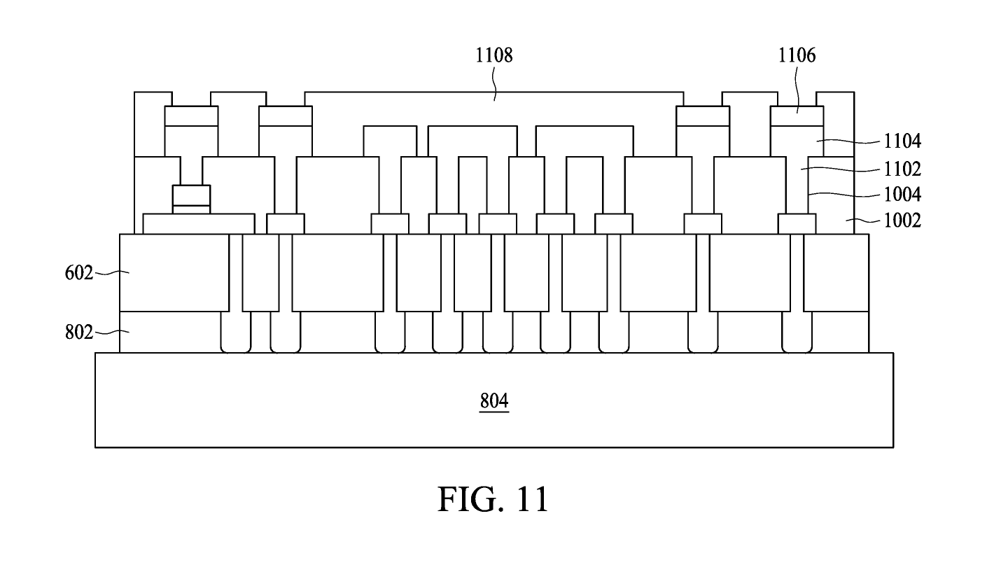

In operation 512, a plurality of conductive vias 1102 are formed in the holes 1004 respectively, as depicted in FIG. 11. Then, a plurality of redistribution layers (RDLs) 1104 are formed on the conductive vias 1102 respectively. A plurality of conductive pads 1106 are formed on at least some of the redistribution layers 1104. Moreover, a second passivation layer 1108 is disposed on at least a portion of the first passivation layer 1002. The material of the conductive vias 1102 and the redistribution layers 1104 may include aluminum (Al). Accordingly, the IPD structure is formed in operations 510 and 512.

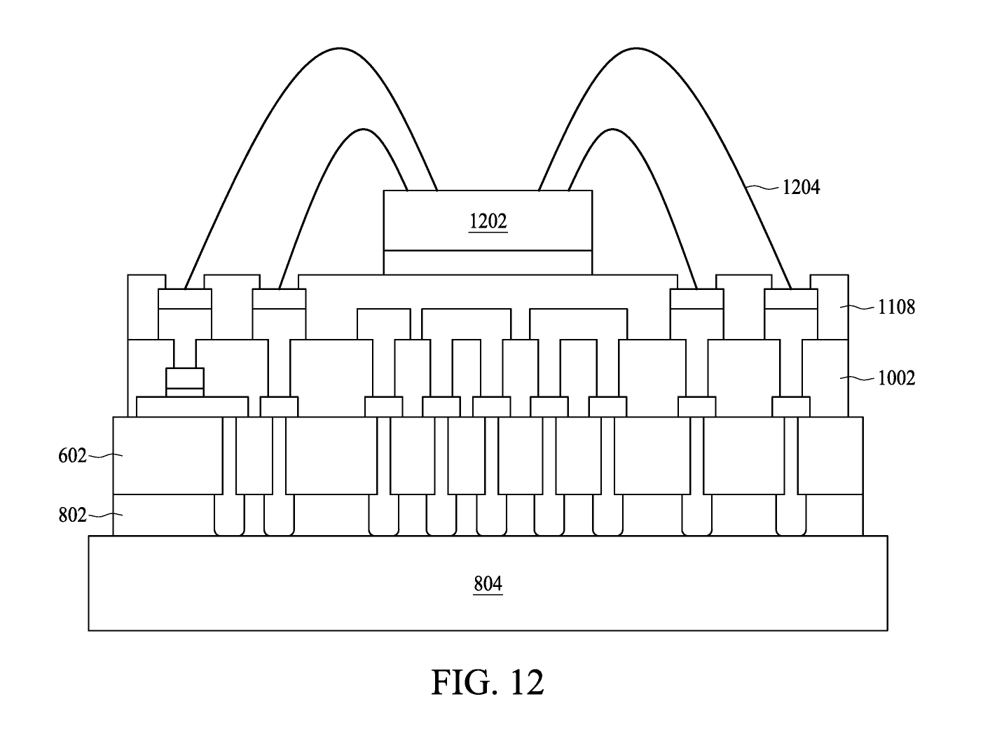

In operation 514, a semiconductor chip 1202 is attached to the second passivation layer 1108, as depicted in FIG. 12, and a wafer level chip-to-wafer wire bonding process is performed. During the wire bonding process, a plurality of bonding wires 1204 are arranged to electrically connect the semiconductor chip 1202 and the conductive pads 1106.

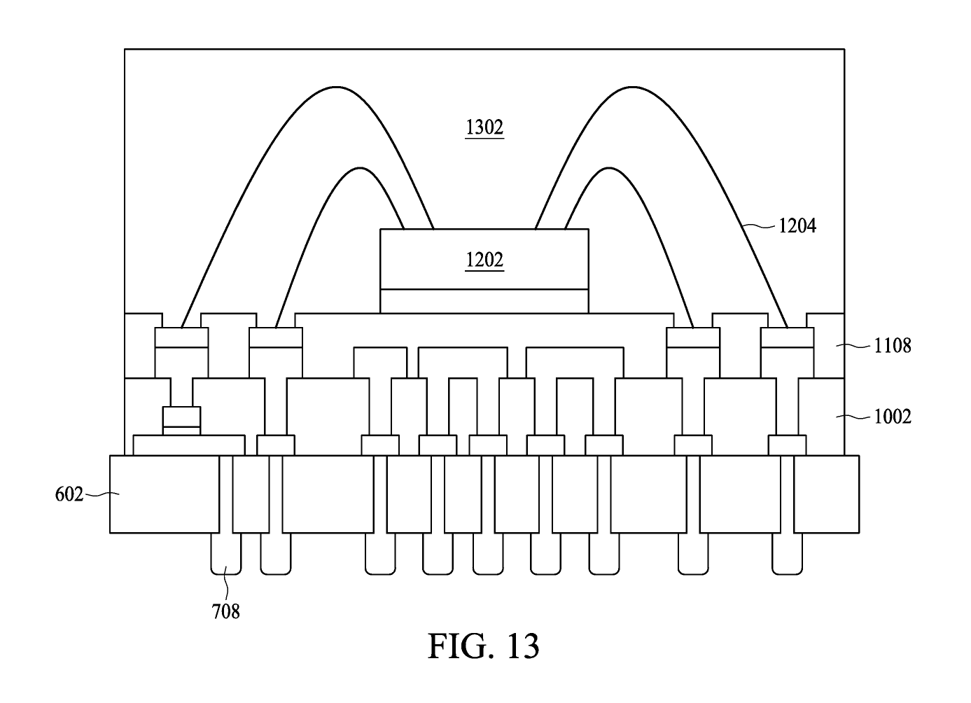

In operation 516, a wafer level molding process is performed, as depicted in FIG. 13. During the molding process, an insulating molding compound 1302 is disposed on the second passivation layer 1108 and covers the semiconductor chip 1202 and the bonding wire 1204. Then, the carrier 804 is released and the adhesive layer 802 is removed. When the adhesive layer 802 is removed, and the conductive bumps 708 are exposed. According to some embodiments, the conductive bumps 708 may undergo a reflowing process for connecting to another circuit board. In other embodiments, the conductive bumps 708 do not undergo the reflowing process. As the conductive bumps 708 are exposed by removing the adhesive layer 802, a solder ball forming process need not be performed. Accordingly, the cost of the semiconductor device package is reduced, and the yield rate and UPH (units per hour) of the semiconductor device packages are improved.

According to some embodiments, in operation 504, the conductive material can be pumped by an injecting device into the holes 604 to form the interconnect structures 706. FIG. 14 is a diagram illustrating a system for forming interconnect structures in accordance with some embodiments. According to some embodiments, the injecting device 1400 is disposed above a glass substrate 1402 and a photoresist layer 1406. The glass substrate 1402 and the photoresist layer 1406 define a plurality of holes 1404. By a photolithography process, the photoresist layer 1406 can be patterned to define a plurality of openings 1408 corresponding to the holes 1404, respectively. The injecting device 1400 includes a slot 1410, a filling head or mechanism 1412, a pumping head or mechanism 1414, and a vacuum head or mechanism 1416. The slot 1410 is filled with a conductive material 1418, such as solder. The filling head 1412 is disposed adjacent to the bottom of the slot 1410 and adjacent to at least one of the openings 1408 of a selected hole 1404. The pumping head 1414 is disposed adjacent to the top of the slot 1410. Gas, such as nitrogen, is pumped into the slot 1410 via the pumping head 1414 and pushes the conductive material 1418 into the selected hole 1404. The injecting device 1400 may follow a predetermined direction 1420 to one-by-one pump the conductive material 1418 into the holes 1404. The vacuum head 1416 is positioned further in the direction 1420 than is the slot 1410. Therefore, the vacuum head 1416 is arranged to first draw air out of the selected hole 1404 such that the selected hole 1404 becomes a vacuum or a near-vacuum. Then, the following filling head 1412 can inject the conductive material 1418 into the selected hole 1404 in a near-vacuum environment. According to some embodiments, the conductive material 1418 is pumped to overflow the holes 1404 and the openings 1408 of the photoresist layer 1406 to form a plurality of conductive bumps 1422. As the interconnect structures 1424 are formed by pumping the conductive material 1418 into the holes 1404 in a near-vacuum environment, the conductive material 1418 can fill the holes 1404 more completely than in a non-vacuum environment. This can help to prevent voids from forming in the holes 1404.

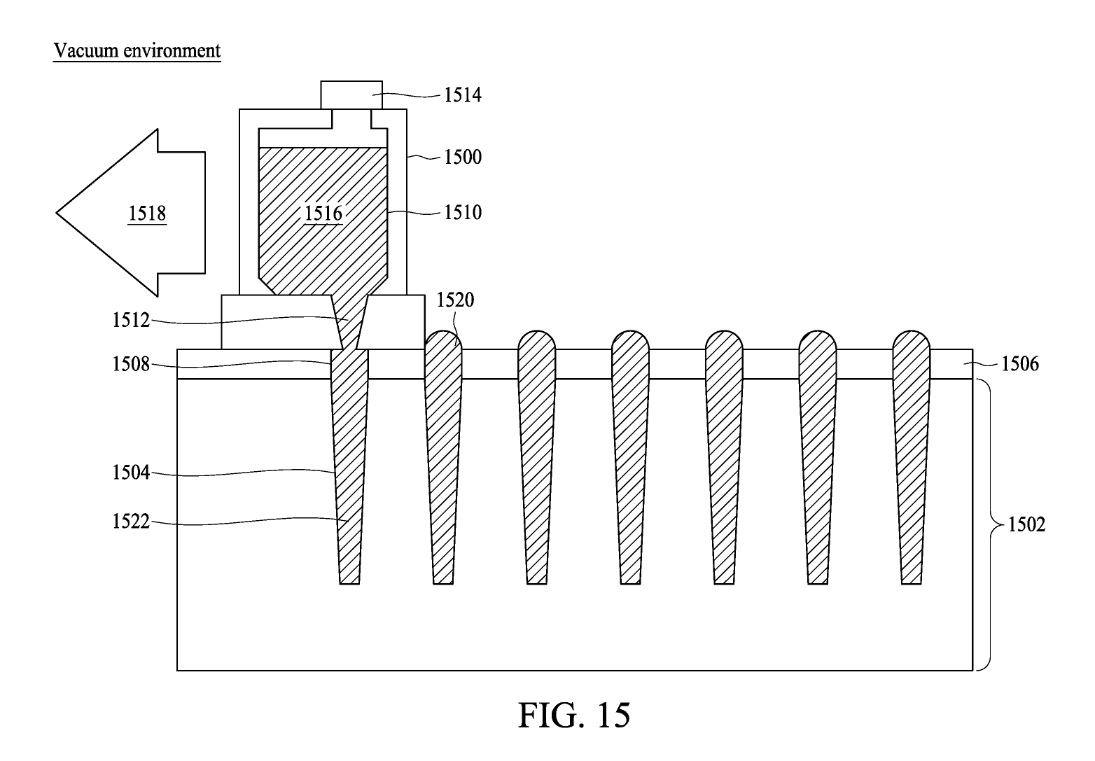

FIG. 15 is a diagram illustrating a system for forming interconnect structures in accordance with some embodiments. According to some embodiments, the injecting device 1500 is disposed above a glass substrate 1502 and a photoresist layer 1506. The glass substrate 1502 and the photoresist layer 1506 can define holes 1504. By a photolithography process, the photoresist layer 1506 can be patterned to define a plurality of openings 1508 that correspond to the holes 1504, respectively. The injecting device 1500 includes a slot 1510, a filling head or mechanism 1512, and a pumping head or mechanism 1514. The slot 1510 is filled with the conductive material 1516, such as solder. The filling head 1512 is disposed at the bottom of the slot 1510 adjacent to at least one of the openings 1408 of a selected hole 1404. The pumping head 1514 is disposed at the top of the slot 1510. Gas, such as nitrogen, is pumped into the slot 1510 via the pumping head 1514 and pushes the conductive material 1516 into the selected hole 1504. The injecting device 1500 may follow a predetermined direction 1518 to one-by-one pump the conductive material 1516 into the holes 1504. According to some embodiments, the injecting device 1500 and the glass substrate 1502 are disposed in a chamber with a near-vacuum environment. Therefore, the injecting device 1500 may pump the conductive material 1516 into the holes 1504 in a near-vacuum environment. According to some embodiments, the conductive material 1516 is pumped to overflow the holes 1504 and the openings 1508 of the photoresist layer 1506 to form a plurality of conductive bumps 1520. As the interconnect structures 1522 are formed by pumping the conductive material 1516 into the holes 1504 in a near-vacuum environment, the conductive material 1516 can be filled in holes 1504 more completely than in a non-vacuum environment. This can help to prevent voids from forming in the holes 1504.

According to some systems, devices and methods of the present disclosure, interconnect structures (e.g., TGVs) and conductive bumps on a glass substrate of a semiconductor device package are formed by directly pumping the conductive material into holes in the glass substrate in a near-vacuum environment. Therefore, the conductive material more completely fill in the holes, and void formation can be avoided. Moreover, as the interconnect structures and the conductive bumps can be formed by a single pumping process, a solder ball forming process need not be performed, and a production cost of the semiconductor device package can be reduced.

As used herein, the singular terms “a,” “an,” and “the” may include plural referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While certain embodiments have been described, these embodiments have been presented by way of example only, and are not intended to limit the scope of the disclosure. Indeed, the embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure. Moreover, some or all of the above described embodiments can be combined when implemented.

What is claimed is:

1. A semiconductor device package, comprising:
a semiconductor chip;
a glass substrate having a first surface facing the semiconductor chip and a second surface opposite to the first surface, the glass substrate defining a hole that traverses the glass substrate from the first surface to the second surface;
an interconnect structure disposed in the hole; and
a conductive bump disposed adjacent to the interconnect structure and protruding from the second surface;
wherein the conductive bump and the interconnect structure comprise a same material.

2. The semiconductor device package of claim 1, wherein the hole comprises a first opening with a first diameter on the first surface and further comprises a second opening with a second diameter on the second surface, wherein the second diameter is greater than the first diameter.

3. The semiconductor device package of claim 2, wherein the hole has a depth measured from the first opening to the second opening, and a ratio of the depth to the second diameter is in a range of 5 to 50.

4. The semiconductor device package of claim 2, wherein a maximum width of the conductive bump is greater than the second diameter.

5. The semiconductor device package of claim 1, wherein the hole comprises a first opening with a first diameter on the first surface and further comprises a second opening with a second diameter on the second surface, wherein the second diameter is substantially equal to the first diameter.

6. The semiconductor device package of claim 1, wherein a diameter of the hole monotonically decreases along a direction from the second surface to the first surface.

7. The semiconductor device package of claim 1, wherein the conductive bump and the interconnect structure comprise tin or an alloy of tin and silver.

8. The semiconductor device package of claim 1, wherein a portion of the conductive bump is in contact with the second surface of the glass substrate.

9. The semiconductor device package of claim 1, wherein the interconnect structure disposed in the hole directly contacts the glass substrate.

10. A semiconductor device package, comprising:
a glass substrate having a first surface and a second surface opposite to the first surface, the glass substrate defining a hole that traverses the glass substrate and comprising a first opening with a first diameter on the first surface and a second opening with a second diameter on the second surface; and
an interconnect structure disposed in the hole;
wherein the second diameter is greater than the first diameter.

11. The semiconductor device package of claim 10, wherein the interconnect structure disposed in the hole directly contacts the glass substrate.

12. The semiconductor device package of claim 10, further comprising:
a conductive bump protruding from the second opening of the hole;
wherein the conductive bump and the interconnect structure comprise a same material.

13. The semiconductor device package of claim 12, wherein the material is tin or an alloy of tin and silver.

14. A system for forming an interconnect structure, comprising:
substrate defining a plurality of holes formed in a surface of the substrate;
an injecting device, disposed above the substrate, the injection device comprising:
a slot, configured to be loaded with a conductive material;
a pumping head disposed adjacent to a top of the slot; and
a filling head, disposed adjacent to a bottom of the slot and configured to fill a selected hole of the plurality of holes to form an interconnect structure;
wherein the pumping head is configured to pump a gas into the slot and to thereby push the conductive material into the selected hole.

15. The system of claim 14, wherein the selected hole is in a near-vacuum state.

16. The system of claim 14, wherein the conductive material comprises tin or alloy of tin and silver, and the gas is nitrogen.

17. The system of claim 14, further comprising:
a photoresist layer disposed on the surface of the substrate that defines a plurality of openings which correspond to respective holes of the plurality of holes;
wherein the injecting device is disposed above the photoresist layer, and the filling head is configured to fill the selected hole with the conductive material via a corresponding opening of the photoresist layer.

18. The system of claim 17, wherein the injecting device is further configured to pump the conductive material to overflow the selected hole and the corresponding opening of the photoresist layer.

19. The system of claim 14, wherein the injecting device further comprises:
a vacuum head, configured to draw air out of the selected hole at least until the selected hole is in a near-vacuum state.

20. The system of claim 19, wherein the injecting device is configured to move in a direction, and the vacuum head is disposed further in the direction than the slot, and the injecting device is thus configured to have the vacuum head draw air out of the selected hole before the filling head fills the conductive material into the selected hole.
